(19) United States
(12) Patent Application Publication
(10) Pub. No.: US 2016/0273127 A1
(43) Pub. Date: Sep. 22, 2016

(54) SUBSTRATE FOR FORMING A SINGLE CRYSTAL LAYER AND METHOD OF PREPARING A SINGLE CRYSTAL LAYER USING THE SUBSTRATE

(71) Applicant: SAMSUNG DISPLAY CO., LTD., Yongin-si (KR)

(72) Inventors: Naotoshi Suganuma, Yokohama (JP); Noriyuki Yoshimoto, Morioka (JP); Ryosuke Kamiya, Morioka (JP)

(21) Appl. No.: 15/071,141

(22) Filed: Mar. 15, 2016

(30) Foreign Application Priority Data
Mar. 16, 2015 (JP) 2015-052155

(51) Int. Cl. C30B 19/12; B32B 3/08; C30B 29/54

(52) U.S. Cl. CPC C30B 19/12; C30B 29/54; B32B 3/08

(57) ABSTRACT

Exemplary embodiments of the inventive concept provide a substrate for forming a single crystal layer with a lyophilic area having a high affinity to a single crystal material to maintain a position of the solution of the single crystal material, and a crystal growth inducing rail part formed in a shape of a line in the lyophilic area and having a higher affinity to the solution of the single crystal material than the lyophilic area.

### CROSS-REFERENCE TO RELATED APPLICATIONS

This application claims priority to and the benefit of Japanese Patent Application No. 2015-052155, filed on Mar. 16, 2015, the entire content of which is hereby incorporated by reference.

### BACKGROUND

Aspects of embodiments of the present disclosure herein relate to substrates for forming a single crystal layer and methods of preparing a single crystal layer using the substrates.

JP2011-181698A discloses a technique for forming a thin film of an organic semiconductor material by using a solution of the organic semiconductor material. In this technique, a lyophilic area and a lyophobic area are formed on a substrate. The lyophilic area is an area that maintains the position of the solution of the organic semiconductor material, and the lyophobic area is an area that repels the solution of the organic semiconductor material. Surfaces that function as the lyophilic area and the lyophobic area are relative (e.g., based on relative affinities to the organic semiconductor material). A surface that functions as the lyophobic area with respect to any lyophilic area may also function as a lyophilic area when the surface is surrounded by a separate area which more strongly repels the solution.

In the technique disclosed in JP11-181698A, a diamagnetic material is used as the organic semiconductor material. In this technique, a liquid layer is first formed on the lyophilic area by providing the solution of the organic semiconductor material to the lyophilic area on the substrate. Thereafter, a magnet is brought in proximity to the liquid layer. As a result, since the solution constituting the liquid layer moves in a direction away from the magnet, a gradient is generated in a thickness of the liquid layer. Specifically, the thickness of a portion of the liquid layer closest to the magnet becomes smaller. The thinner portion of the liquid layer transforms into a supersaturated state. A crystal of the organic semiconductor material is precipitated from the thinner portion. Thereafter, a crystal of the organic semiconductor material is grown by using the corresponding crystal as a crystal nucleus. The crystal is grown in the direction away from the magnet. As a result, a single crystal layer of the organic semiconductor material is formed.

In the technique disclosed in JP2011-181698A, a precipitation position of the crystal nucleus and a growth direction of the crystal are controlled by using the diamagnetic material as the organic semiconductor material and bringing the magnet into proximity with the liquid layer. In addition, JP2011-181698A discloses the preparation of a large-area single crystal layer by this technique.

### SUMMARY

However, accidental precipitation of the crystal nucleus may result by the technique described in JP2011-181698A. Specifically, crystals are precipitated from various portions of the liquid layer at the same time. Then, each crystal becomes a crystal nucleus and the crystals are grown. As a result, a polycrystalline layer is formed instead of a single crystal layer. In addition, the crystals grown from each crystal nucleus may disappear due to a difference in the preference of crystal orientation in a growth process. A single crystal layer may form if all of the crystals disappear except for the crystal grown in a set or predetermined direction. However, since the reproducibility of the disappearance of the crystals is not guaranteed, a single crystal layer is not necessarily formed by the disappearance of the crystals.

Thus, there is a limitation in that a single crystal layer may not be stably prepared by the technique described in JP2011-181698A.

Aspects of embodiments of the present disclosure are directed toward a novel and improved substrate for forming a single crystal layer which may more stably prepare a single crystal layer, and a method of preparing a single crystal layer using the substrate.

Some embodiments of the inventive concept provide a substrate for forming a single crystal layer which may include a lyophilic area capable of maintaining a position solution of a single crystal material and a crystal growth inducing rail part formed in the shape of a line (e.g., belt-shaped) in the lyophilic area. The crystal growth inducing rail part may have a higher affinity to the solution of the single crystal material than that of the lyophilic area.

In some embodiments, a single crystal layer may be grown by selectively forming a crystal nucleus on the crystal growth inducing rail part and using the crystal nucleus as a starting point. Thus, the single crystal layer may be more stably prepared.

In some embodiments, the crystal growth inducing rail part may be formed across both ends of the lyophilic area in a crystal growth direction. In such embodiments, a single crystal layer may be more stably prepared.

In some embodiments, an end portion of the crystal growth inducing rail part in a width direction (e.g., in a direction substantially perpendicular to the crystal growth direction) may be formed closer to the center of the lyophilic area than an end portion of the lyophilic area. In such embodiments, a single crystal layer may be more stably prepared.

In some embodiments, one end portion of the crystal growth inducing rail part in a longitudinal direction may be formed in the shape of an acute angle. In such embodiments, a single crystal layer may be more stably prepared.

In some embodiments, the acute angle of the one end portion of the crystal growth inducing rail part may be in a range of about 30° to about 45°. In such embodiments, a single crystal layer may be more stably prepared.

In some embodiments of the inventive concept, a method of preparing a single crystal layer utilizing the substrate for forming a single crystal layer includes: providing a solution of a single crystal material on a lyophilic area and a crystal growth inducing rail part, and moving the solution of the single crystal material from one end portion of the crystal growth inducing rail part in a longitudinal direction toward another end portion of the crystal growth inducing rail part.

In some embodiments, a single crystal layer may be grown by selectively forming a crystal nucleus on the crystal growth inducing rail part and utilizing the crystal nucleus as a starting point. Thus, the single crystal layer may be more stably prepared.

### BRIEF DESCRIPTION OF THE DRAWINGS

The above and other advantages of the present disclosure will become readily apparent by reference to the following detailed description when considered in conjunction with the accompanying drawings wherein:

FIG. 1 is a plan view illustrating an example of a substrate for forming a single crystal layer according to some embodiments of the inventive concept;

FIG. 2 is an enlarged plan view illustrating a layer formation area of FIG. 1;

FIG. 3 is a plan view illustrating another example of the layer formation area according to some embodiments;

FIG. 4 is a plan view illustrating another example of the layer formation area according to some embodiments;

FIG. 5 (a) is a plan view for illustrating a preparation process of the substrate for forming a single crystal layer according to some embodiments, and FIG. 5 (b) is a cross-sectional view taken along line A-A′ of FIG. 5 (a);

FIG. 6 (a) is a plan view for illustrating the preparation process of the substrate for forming a single crystal layer according to some embodiments, and FIG. 6 (b) is a cross-sectional view taken along line A-A′ of FIG. 6 (a);

FIG. 7 (a) is a plan view for illustrating the preparation process of the substrate for forming a single crystal layer according to some embodiments, and FIG. 7 (b) is a cross-sectional view taken along line A-A′ of FIG. 7 (a);

FIG. 8 (a) is a plan view for illustrating the preparation process of the substrate for forming a single crystal layer according to some embodiments, and FIG. 8 (b) is a cross-sectional view taken along line A-A′ of FIG. 8 (a);

FIG. 9 (a) is a plan view for illustrating the preparation process of the substrate for forming a single crystal layer according to some embodiments, and FIG. 9 (b) is a cross-sectional view taken along line A-A′ of FIG. 9 (a);

FIG. 10 (a) is a plan view for illustrating the preparation process of the substrate for forming a single crystal layer according to some embodiments, and FIG. 10 (b) is a cross-sectional view taken along line A-A′ of FIG. 10 (a); and

FIG. 11 is a plan view illustrating a state in which a crystal is grown on the layer formation area according to some embodiments.

### DETAILED DESCRIPTION

Hereinafter, exemplary embodiments of the inventive concept will be described below in detail with reference to the accompanying drawings. Also, in the specification and drawings, the same reference numerals will be assigned to elements having substantially the same function or configuration, and the overlapping descriptions thereof are omitted.

In the drawings, the thickness of layers, films, and regions may be exaggerated for clarity. It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present.

The terminology used herein is for the purpose of describing particular embodiments only and is not intended to be limiting of the present invention. As used herein, the singular forms “a” and “an” are intended to include the plural forms as well, unless the context clearly indicates otherwise. It will be further understood that the terms “comprises,” “comprising,” “includes,” and “including,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

As used herein, the terms “substantially,” “about,” and similar terms are used as terms of approximation and not as terms of degree, and are intended to account for the inherent deviations in measured or calculated values that would be recognized by those of ordinary skill in the art. Further, the use of “may” when describing embodiments of the present invention refers to “one or more embodiments of the present invention.” As used herein, the terms “use,” “using,” and “used” may be considered synonymous with the terms “utilize,” “utilizing,” and “utilized,” respectively. Also, the term “exemplary” is intended to refer to an example or illustration.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

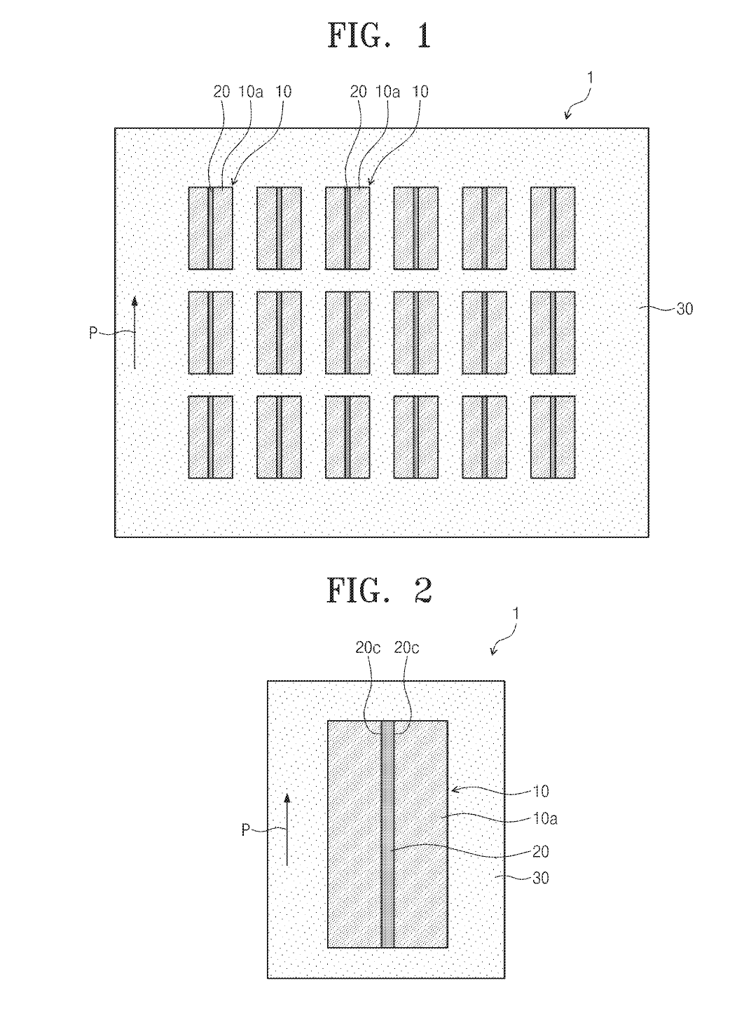

A configuration of a substrate 1 for forming a single crystal layer 50 according to some embodiments will be described with reference to FIGS. 1 and 2. The substrate 1 for forming a single crystal layer 50 may include a substrate member 1a (see FIG. 10), a plurality of layer formation areas 10, and one or more lyophobic areas 30.

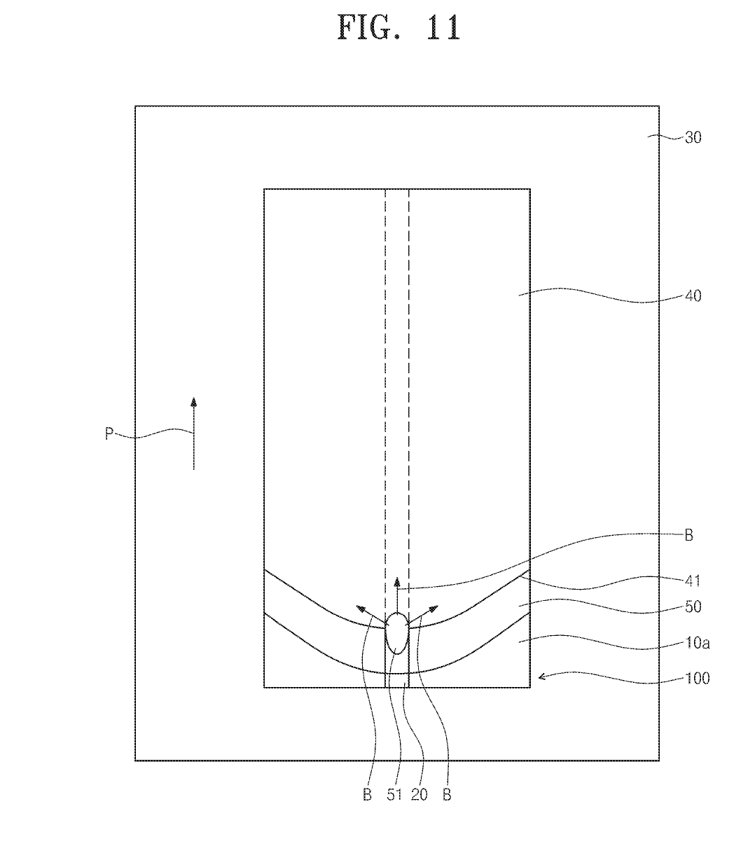

The substrate member 1a may be a plate-shaped member on which layer formation areas 10 and lyophobic areas 30 are formed. The substrate member 1a material may be appropriately selected depending on the intended use of a single crystal layer 50 (see, e.g., FIG. 11) prepared by the present embodiments. The substrate member 1a may be made of glass, plastic, a silicon single crystal, and/or various metals, but is not limited thereto or thereby. The substrate member 1a may be covered with a silicon oxide layer. A lyophilic area 10a and the lyophobic area 30 may be formed on a surface of the substrate member 1a.

The layer formation area 10 is an area on which the single crystal layer 50 may be formed. The layer formation area 10 may include one or more lyophilic areas 10a and one or more crystal growth inducing rail parts 20. The lyophilic area 10a is an area which maintains a position of a solution of a single crystal material to prevent the flow of the single crystal material (e.g., towards the lyophobic area 30) and fix the single crystal material. The lyophilic area 10a is an area in which an affinity to the solution of the single crystal material is higher than that of the lyophobic area 30 and is lower than that of the crystal growth inducing rail part 20. The lyophilic area 10a, for example, may be made of a self-organization monomolecular layer.

Examples of a monomolecule constituting a self-organization monomolecular layer may be chlorosilane compounds having an alkyl group, such as 1,1,1,3,3,3-hexamethyldisilazane, octyltrichlorosilane, and octadecyltrichlorosilane, or alkoxy compounds. The self-organization monomolecular layer may be formed by exposing the substrate member 1a to a vapor, solution, or stock solution of the monomolecule. The surface of the substrate member 1a may additionally or alternatively be used as a lyophilic area 10a.

In FIG. 1, arrow P represents a crystal growth direction of a uniform single crystal layer 50. The crystal growth direction coincides with a longitudinal direction of the crystal growth inducing rail part 20 (i.e., a substantially vertical direction in FIG. 1). To form a uniform single crystal layer 50, a width of the lyophilic area 10a, (i.e., a width of the layer formation area 10) may be about 10 mm or less, but is not limited thereto or thereby. In some embodiments, a width of the lyophilic area 10a of about 10 mm or less may facilitate formation of a uniform single crystal layer 50. The width of the layer formation area 10 is in a direction perpendicular to a crystal growth direction (i.e., a substantially horizontal direction in FIG. 1). A length of the lyophilic area 10a (i.e., a length of the layer formation area 10) in the crystal growth direction is not particularly limited.

In FIG. 1, although the planar shape of the lyophilic area 10a (i.e., the shape when the lyophilic area 10a is in a plan view) is depicted as a rectangle which extends in the crystal growth direction, the shape of the lyophilic area 10a is not limited thereto or thereby. It should be appreciated that the lyophilic area 10a may have other shapes, such as the shapes described herein below.

The crystal growth inducing rail part 20 may be formed in the shape of a line (e.g., belt-shaped) in the lyophilic area 10a (e.g., with the lyophilic area 10a on either side of the crystal growth inducing rail part 20). The longitudinal direction of the crystal growth inducing rail part 20 coincides with the crystal growth direction. The crystal growth inducing rail part 20 has a higher affinity to the solution of the single crystal material than the lyophilic area 10a. Specifically, a contact angle of the crystal growth inducing rail part 20 with the solution of the single crystal material may be smaller than a contact angle of the lyophilic area 10a with the corresponding solution. The contact angle of the crystal growth inducing rail part 20 with the solution of the single crystal material may be smaller than the contact angle of the lyophilic area 10a with the corresponding solution by about 20° or more. In addition, the contact angle of the crystal growth inducing rail part 20 with the solution of the single crystal material may be less than 10°.

The crystal growth inducing rail part 20, for example, may be made of a self-organization monomolecular layer. Examples of a monomolecule constituting the self-organization monomolecular layer may be chlorosilane compounds having a phenyl group at an end thereof, such as (2-phenylethyl)trimethoxysilane and 3-(phenylam ino)propyltrimethoxysilane, or alkoxy compounds. The self-organization monomolecular layer may be formed by exposing the substrate member 1a to a vapor, solution, or stock solution of the monomolecule.

The crystal growth inducing rail part 20 may act as a guide for the growth of a single crystal (e.g., by the above described configuration of the crystal growth inducing rail part 20). As described above, the contact angle of the crystal growth inducing rail part 20 with the solution of the single crystal material is smaller than the contact angle of the lyophilic area 10a with the corresponding solution. In some exemplary embodiments, a single crystal may be grown by the following preparation method. First, a solution of single crystal material may be provided on the layer formation area 10 (e.g., on the crystal growth inducing rail part 20 and/or lyophilic area 10a). Thereafter, the solution of single crystal material is moved from one end portion of the crystal growth inducing rail part 20 in the longitudinal direction towards another end portion of the crystal growth inducing rail part 20. For example, the solution may be moved in a direction of the arrow P as depicted in FIG. 1. Accordingly, a droplet end may be formed on the layer formation area 10. A thickness of the droplet end on the crystal growth inducing rail part 20 becomes smaller than a thickness of the droplet end on the lyophilic area 10a based on the above described relative affinities to the crystal material and contact angles (e.g., more solvent may be located in the droplet end on the lyophilic area 10a than the crystal growth inducing rail part 20). Moreover, even if solvent is evaporated from the droplet end on the crystal growth inducing rail part 20, it is difficult for the solvent to be transferred to the droplet end on the crystal growth inducing rail part 20 from the surrounding droplet ends. As a result, the droplet end on the crystal growth inducing rail part 20 may be in a supersaturated state, and the single crystal material may be precipitated as a crystal onto the crystal growth inducing rail part 20. Since a larger amount of the solvent remains in the droplet end on the lyophilic area 10a than in the droplet end on the crystal growth inducing rail part 20, it is difficult to precipitate the single crystal material in the lyophilic area 10. Thus, a crystal nucleus may be selectively formed on the crystal growth inducing rail part 20. A single crystal may be grown by using the crystal nucleus as a starting point of the crystal growth. Thereafter, since the solution moves in the direction of the arrow P, the droplet end also moves in the direction of the arrow P. Following movement of the droplet end in the direction of the arrow P, the crystal nucleus may also be selectively formed on additional locations on the crystal growth inducing rail part 20, and the single crystal is grown by using the crystal nucleus as a starting point of the crystal growth.

Since the single crystal is grown along the longitudinal direction of the crystal growth inducing rail part 20, the crystal growth inducing rail part 20 may act as a guide for single crystal growth. In addition, the crystal growth direction coincides with the longitudinal direction of the crystal growth inducing rail part 20.

The crystal growth inducing rail part 20 may be formed to extend across both ends of the lyophilic area 10a in the crystal growth direction (i.e., the ends in the longitudinal direction of the crystal growth inducing rail part 20). In such a case, a more uniform single crystal layer 50 may be formed on the layer formation area 10. In FIG. 1, the crystal growth inducing rail part 20 extends across both ends of the lyophilic area 10a in the crystal growth direction.

An end portion 20c of the crystal growth inducing rail part 20 in a width direction (i.e., in a direction substantially perpendicular to the longitudinal direction of the crystal growth inducing rail part 20) may be formed closer to the center of the lyophilic area 10a than an end portion of the lyophilic area 10a in a width direction (see FIG. 2). Specifically, the crystal growth inducing rail part 20 may be formed near the center of the lyophilic area 10a in the width direction. The crystal growth inducing rail part 20 may act as a guide during the growth of the crystal. Thus, since the crystal growth inducing rail part 20 is located near the center of the lyophilic area 10a, a single crystal may be grown near the center of the lyophilic area 10a. Therefore, a more uniform single crystal may be formed.

In some embodiments, a width of the crystal growth inducing rail part 20 is not particularly limited. In addition, in embodiments in which the solution of the single crystal material is provided on the layer formation area 10 (e.g., on the crystal growth inducing rail part 20 and the lyophilic area 10a), the droplet end on the crystal growth inducing rail part 20 may protrude outward more than the droplet end on the lyophilic area 10a. An amount of the droplet end that protrudes outward may depend on the width of the crystal growth inducing rail part 20. In some embodiments, the width of the crystal growth inducing rail part 20 may be adjusted so that the amount of the droplet end protruding outward may be in a range of about 0.5 mm to about 1.0 mm. In some embodiments, an amount of the droplet end on the crystal growth inducing rail part 20 protruding outward within the above range may facilitate forming a crystal nucleus on the crystal growth inducing rail part 20.

The width of the crystal growth inducing rail part 20 depends on surface tension of the solution of the single crystal material (e.g., based on the surface tension of the solvent). For example, with respect to a solution composed of monochlorobenzene, toluene, and tetralin, in which surface tension is between about 30 mN/m and about 40 mN/m, it may be desirable to adjust the width of the crystal growth inducing rail part 20 to be between about 1 mm and about 2 mm. With respect to a solution in which surface tension is much greater than about 40 mN/m, it may be desirable to adjust the width of the crystal growth inducing rail part 20 to be greater than about 2 mm, and with respect to a solution in which surface tension is much less than about 30 mN/m, it may be desirable to adjust the width of the crystal growth inducing rail part 20 to be less than about 1 mm.

The lyophobic area 30 repels the solution of the single crystal material and may be formed around the lyophilic area 10a (see, e.g., FIG. 1). The lyophobic area 30 has a lower affinity to the solution of the single crystal material than the lyophilic area 10a. Specifically, a contact angle of the lyophobic area 30 with the solution of the single crystal material may be greater than the contact angle of the lyophilic area 10a with the solution of the single crystal material. The lyophobic area 30, for example, may be made of a self-organization monomolecular layer. Examples of a monomolecule constituting the self-organization monomolecular layer may be chlorosilane compounds having a fluorine-containing group, such as 1H,1H,2H,2H-perfluorooctyltrichlorosilane, or alkoxy compounds. The self-organization monomolecular layer may be formed by exposing the substrate member 1a to a vapor, solution, or stock solution of the monomolecule.

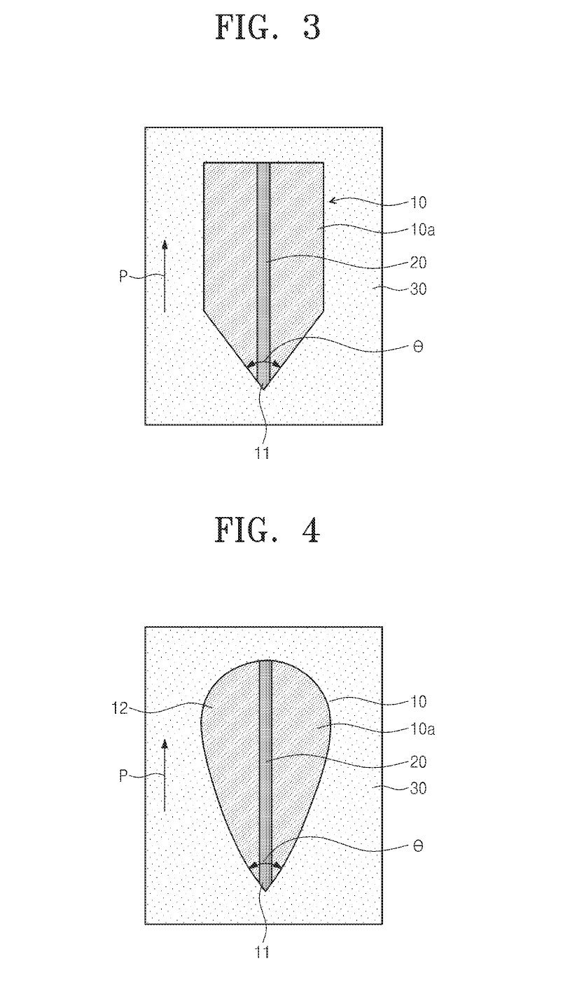

A first modified example of the layer formation area 10 according to some embodiments will be described with reference to FIG. 3. In the first modified example, one end portion 11 of the layer formation area 10 in the crystal growth direction may have the shape of an acute angle. That is, one end portion of the crystal growth inducing rail part 20 in the longitudinal direction may have the shape of an acute angle. An angle θ of the one end portion 11 of the layer formation area 10 may be less than about 90°. For example, the angle θ of the one end portion 11 having the shape of an acute angle may be in a range of about 30° to about 45°. In the first modified example, a crystal nucleus may be selectively formed in an acute angle portion of the crystal growth inducing rail part 20. In such embodiments, the formation of the crystal nucleus and the growth of the single crystal may be more precisely controlled.

A second modified example of the layer formation area 10 according to some embodiments will be described with reference to FIG. 4. In the second modified example, one end portion 11 of the layer formation area 10 in the crystal growth direction may have the shape of an acute angle and another end portion 12 of the layer formation area 10 in the crystal growth direction may have a semicircular shape. The same effect as the first modified example may be obtained in the second modified example. In addition, in the second modified example, a crystal nucleus may be more reliably formed in an acute angle portion of the crystal growth inducing rail part 20.

A width of the layer formation area 10 in the embodiments depicted in FIGS. 3 and 4 corresponds to a maximum width of the layer formation area 10 (i.e., width of rectangular portion in FIG. 3 and diameter of semicircular portion in FIG. 4). A length of the layer formation area 10 coincides with a length of the crystal growth inducing rail part 20.

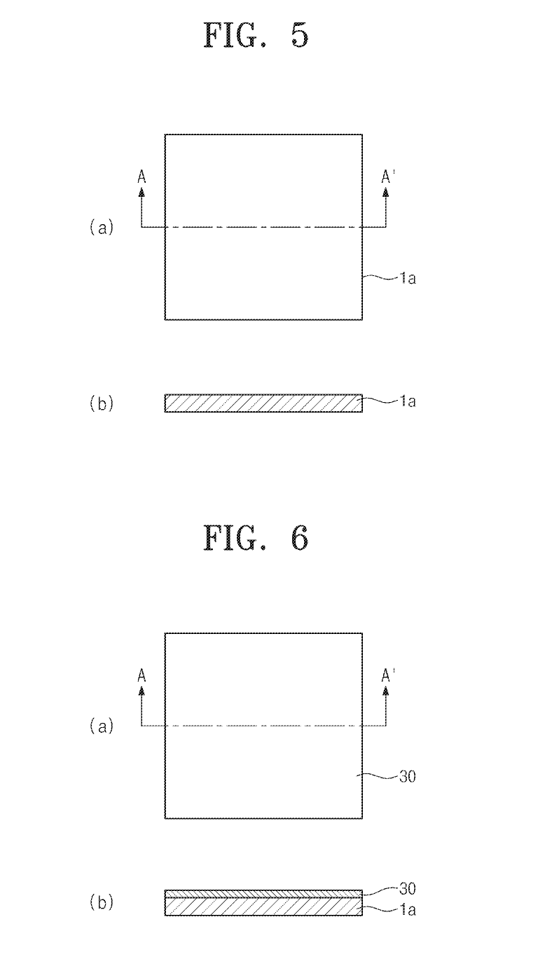

Methods of fabricating the substrate 1 for forming a single crystal layer 50 according to some embodiments will be described with reference to FIGS. 5 to 10. First, as illustrated in FIG. 5, the substrate member 1a may be prepared. The substrate member 1a may be washed with an organic solvent and ultrapure water, and a ultraviolet (UV)-ozone cleaning treatment may then performed. As a result, the surface of the substrate member 1a may become lyophilic.

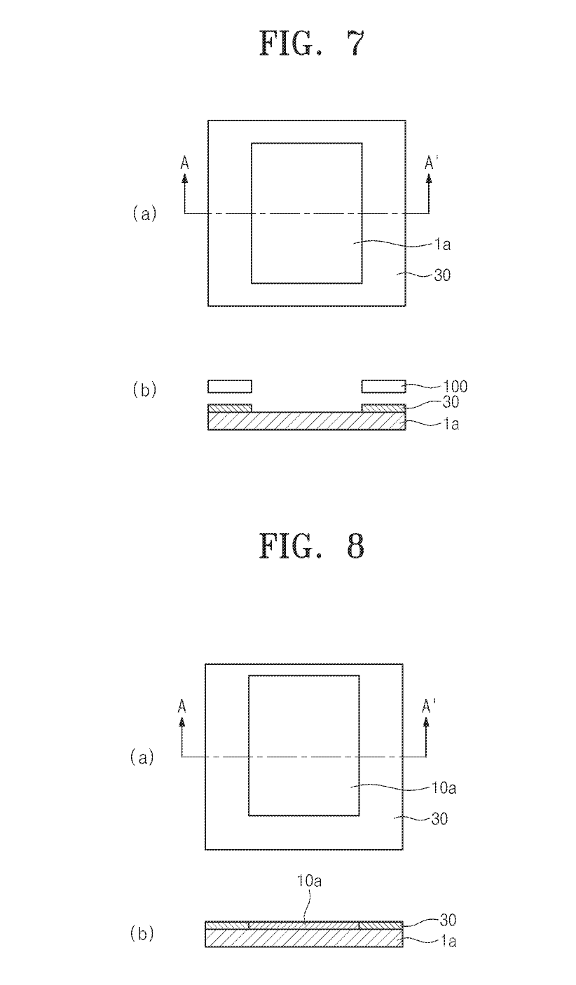

Subsequently, as illustrated in FIG. 6, the substrate member 1a may be exposed to a vapor, solution, or stock solution of a lyophobic self-organization monomolecule. As a result, a lyophobic self-organization monomolecular layer may be formed on the substrate member 1a (i.e., the lyophobic area 30). Subsequently, as illustrated in FIG. 7, a shadow mask 100 having a hole in the shape of the lyophilic area 10a may be closely attached to a surface of the lyophobic area 30. The shadow mask 100 may be placed over portions of the lyophobic area 30 which are not designed to be removed. The self-organization monomolecular layer which is not covered with the shadow mask 100 may be removed. The removal of the self-organization monomolecular layer may be performed, for example, by using a UV-ozone treatment and/or oxygen plasma treatment. As a result, an exposed surface of the substrate member 1a may be formed. The exposed surface may have a planar shape of the desired lyophilic area 10a.

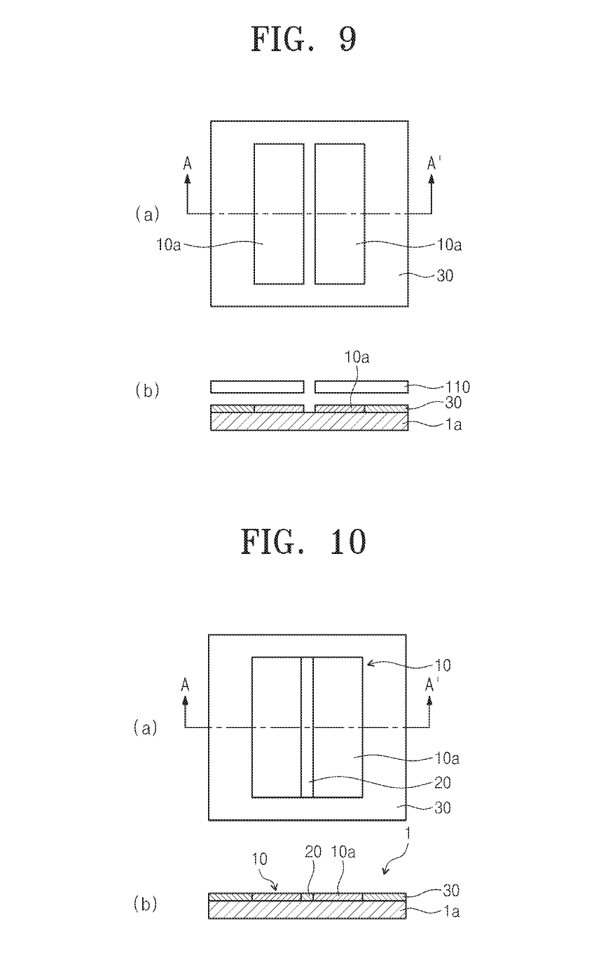

Subsequently, as illustrated in FIG. 8, the substrate member 1a may be exposed to a vapor, solution, or stock solution of a lyophilic self-organization monomolecule. As a result, a lyophilic self-organization monomolecular layer may be formed on the exposed surface of the substrate member 1a (i.e., the lyophilic area 10a). Subsequently, as illustrated in FIG. 9, a shadow mask 110 having a hole in the shape of the crystal growth inducing rail part 20 may be closely attached to a surface of the lyophilic area 10a. The shadow mask 110 may be placed over portions of the lyophilic area 30 which are not designed to be removed. The self-organization monomolecular layer which is not covered with the shadow mask 110 may be removed. The removal of the self-organization monomolecular layer may be performed, for example, by using a UV-ozone treatment and/or oxygen plasma treatment. As a result, an exposed surface of the substrate member 1a may be formed. The exposed surface may have a planar shape of the desired crystal growth inducing rail part 20.

Subsequently, as illustrated in FIG. 10, the substrate member 1a may be exposed to a vapor, solution, or stock solution of a lyophilic self-organization monomolecule. The self-organization monomolecule may have a higher affinity to the solution of the single crystal material than the self-organization monomolecule constituting the lyophilic area 10a. As a result, a lyophilic self-organization monomolecular layer may be formed on the exposed surface of the substrate member 1a (i.e., the crystal growth inducing rail part 20). The substrate 1 for forming a single crystal layer 50 may be fabricated by the above processes. In some embodiments, the substrate 1 for forming a single crystal layer 50 may be fabricated by printing materials of the layer formation area 10 (i.e., the lyophilic area 10a and the crystal growth inducing rail part 20) and the lyophobic area 30 (e.g., by screen printing, gravure printing, offset lithography, and/or the like). Different methods may be used to fabricate the substrate 1 for forming a single crystal layer 50.

Methods of preparing a single crystal layer 50 by using the substrate 1 for forming a single crystal layer 50 according to some embodiments will be described with reference to FIG. 11. First, a solution 40 of the single crystal material may be provided on the layer formation area 10 (e.g., on the crystal growth inducing rail part 20 and/or lyophilic area 10a). Subsequently, the solution 40 may be moved from one end portion of the crystal growth inducing rail part 20 in the longitudinal direction toward another end portion of the crystal growth inducing rail part 20. For example, the solution may be moved in the direction of the arrow P. In addition, the method of moving the solution 40 is not particularly limited. The method of moving the solution 40 may include use of a magnetic field and/or use of a temperature gradient.

A droplet end 41 may be formed on the layer formation area 10. A thickness of the droplet end 41 on the crystal growth inducing rail part 20 may become smaller than a thickness of the droplet end 41 on the lyophilic area 10a based on the above described relative affinities to the crystal material and contact angles (e.g., more solvent may be located in the droplet end on the lyophilic area 10a than the crystal growth inducing rail part 20). Moreover, even if solvent is evaporated from the droplet end 41 on the crystal growth inducing rail part 20, it is difficult for the solvent to be transferred to the droplet end 41 on the crystal growth inducing rail part 20 from the surrounding droplet ends 41. As a result, the droplet end 41 on the crystal growth inducing rail part 20 may be in a supersaturated state, and the single crystal material may be precipitated as a crystal. Since a larger amount of the solvent remains in the droplet end 41 on the lyophilic area 10a than in the droplet end on the crystal growth inducing rail part 20, it is difficult to precipitate the single crystal material in the lyophilic area 10. Thus, a crystal nucleus 51 may be selectively formed on the crystal growth inducing rail part 20. A single crystal layer 50 may be grown by using the crystal nucleus 51 as a starting point of the crystal growth. For example, the single crystal layer 50 may be grown in a direction of an arrow B in FIG. 11 by using the crystal nucleus 51 as a starting point. Thereafter, since the solution moves in the direction of the arrow P, the droplet end also moves in the direction of the arrow P. Following movement of the droplet end in the direction of the arrow P, the crystal nucleus 51 may also be selectively formed on additional locations on the crystal growth inducing rail part 20, and the single crystal layer 50 may be grown by using the crystal nucleus 51 as a starting point of the crystal growth. The above processes may be performed on the layer formation area 10 until the entire solvent is evaporated. A single crystal layer 50 may be formed on the layer formation area 10 by the above processes.

In some exemplary embodiments, because a crystal nucleus may be selectively precipitated on the crystal growth inducing rail part 20, a single crystal may be grown by using the crystal nucleus as a starting point. Thus, the single crystal layer 50 may be more stably prepared.

A first example (“Example 1”) confirming the formation of a single crystal layer 50 by the above-described exemplary embodiments will be described herein. A configuration of the substrate 1 for forming a single crystal layer 50, which was used in Example 1, is as follows in Table 1.

TABLE 1

| Component | Material/Value |
|---|---|
| Single crystal material | TIPS-pentacene |
| | (6,13bis(triisopropylsilylethynyl) |
| | pentacene) |
| Solvent | monochlorobenzene |
| Concentration of single crystal | 10 mg/ml |
| material solution | |
| Substrate member 1a | oxide layer-attached silicon wafer |
| Number of layer formation areas 10 | 100 |
| Shape of the layer formation area 10 | rectangle (length in crystal growth |
| | direction: 15 mm, width: 10 mm) |
| Shape of the crystal growth inducing | rectangle (length in crystal growth |
| rail part 20 | direction: 15 mm, width: 1 mm) |
| Self-organization monomolecular | 1,1,1,3,3,3-hexamethyldisilazane |
| layer constituting the lyophilic area | (contact angle with |
| 10a | monochlorobenzene: 26°) |
| Self-organization monomolecular | 2-phenylethyl)trimethoxysilane |
| layer constituting the crystal growth | (contact angle with monochloro- |
| inducing rail part 20 | benzene: 3° to 5°) |
| Self-organization monomolecular | 1H,1H,2H,2H-perfluorooctyl- |
| layer constituting the lyophobic area | trichlorosilane (contact angle with |
| 30 | monochlorobenzene: 60°) |

The substrate 1 for forming a single crystal layer 50 according to Example 1 has a structure corresponding to the embodiments illustrated in FIG. 1. The contact angle was measured using a tangential method.

To create the Example 1, first, the solution of the single crystal material was provided on each layer formation area 10 of the substrate 1 for forming a single crystal layer 50. Subsequently, the solution of the single crystal material was moved in the direction of the arrow P (see FIG. 1) by applying a magnetic field to the substrate 1 for forming a single crystal layer 50. Accordingly, a droplet end was formed on the layer formation area 10. Subsequently, the application of the magnetic field was stopped and an amount of the droplet end protruding outward on the crystal growth inducing rail part 20 was measured. The amount of the droplet end protruding outward on the crystal growth inducing rail part 20 was in a range of about 0.5 mm to about 1.0 mm. Thereafter, the application of the magnetic field was resumed. As a result, in each layer formation area 10, a crystal nucleus was selectively precipitated from the crystal growth inducing rail part 20, and a crystal layer was grown from the crystal nucleus.

The crystal layers were formed on all of the layer formation areas 10, and a ratio of an area of the single crystal layer 50 in the crystal layer was then calculated by using a polarized light microscope. Specifically, almost all areas in the layer formation area 10 were observed as bright-field areas by rotating an analyzer (e.g., to a first orientation). Thereafter, the analyzer was rotated by about 45°. As a result, at least a portion of the area in the layer formation area 10 was changed to a dark-field area. Since it may be estimated that the single crystal layer 50 was formed in the area in which the bright-field area is changed to the dark-field area, the changed area was calculated as the area of the single crystal layer 50. Then, the ratio of the area of the single crystal layer 50 was calculated by dividing the area of the single crystal layer 50 by an area of one of the layer formation areas 10 (about 150 mm²). The ratios of the areas of the single crystal layers 50 in all of the layer formation areas 10 were then calculated. As a result, the single crystal layer 50 was formed with an average area ratio of about 75% (arithmetic mean of the area ratios in the layer formation areas 10). A single-domain crystal layer was formed in an area in the crystal growth inducing rail part 20 among areas in which the single crystal layer 50 was not formed.

As a comparative example, a sample was created having the same treatment as in Example 1 except that the crystal growth inducing rail part 20 was not formed in the layer formation area 10. As a result, a crystal nucleus was randomly formed in the layer formation area 10. Thus, a single crystal layer 50 may not result in each layer formation area 10 in the comparative example.

A second example (“Example 2”) was created having the same treatment as in Example 1 except that the shape of the layer formation area 10 corresponded to the embodiments illustrated in FIG. 4. In addition, the width and length of the layer formation area 10 had the same dimensions as those of Example 1, and the width and length of the crystal growth inducing rail part 20 also had the same dimensions as those of Example 1. The angle of the acute angle portion was about 30°. As a result, the single crystal layer 50 was formed with an average area ratio of about 92% (arithmetic mean of the area ratios in the layer formation areas 10). The same result was obtained when the angle of the acute angle portion was about 45°. Thus, in a case in which one end portion of the crystal growth inducing rail part 20 was made to be in the shape of an acute angle, the formation of the crystal nucleus and the growth of the single crystal may be more precisely controlled.

As described above, according to one or more embodiments of the inventive concept, a single crystal layer 50 may be grown by selectively forming a crystal nucleus on a crystal growth inducing rail part and using the crystal nucleus as a starting point. Thus, the single crystal layer 50 may be more stably prepared.

Although embodiments of the inventive concept have been shown and described with reference to the accompanying drawings, the scope of the inventive concept is not limited to the embodiments. It will be understood by those of ordinary skill in the art that various changes and modifications of the embodiments may be made without departing from the spirit and scope of the inventive concept as defined by the appended claims and equivalents thereof, and the changes and modifications are included in the scope of the inventive concept.

What is claimed is:

1. A substrate for forming a single crystal layer, the substrate comprising:
a lyophilic area having a high affinity to a single crystal material to maintain a position of a solution of the single crystal material; and
a crystal growth inducing rail part having a shape of a line in the lyophilic area and having a higher affinity to the solution of the single crystal material than that of the lyophilic area.

2. The substrate for forming a single crystal layer of claim 1, wherein the crystal growth inducing rail part is formed across both ends of the lyophilic area in a crystal growth direction of the single crystal material.

3. The substrate for forming a single crystal layer of claim 2, wherein an end portion of the crystal growth inducing rail part in a width direction substantially perpendicular to the crystal growth direction is formed closer to a center of the lyophilic area than an end portion of the lyophilic area.

4. The substrate for forming a single crystal layer of claim 3, wherein one end portion of the crystal growth inducing rail part in a longitudinal direction is in a shape of an acute angle.

5. The substrate for forming a single crystal layer of claim 1, wherein an end portion of the crystal growth inducing rail part in a width direction substantially perpendicular to a longitudinal direction of the crystal growth inducing rail part is formed closer to a center of the lyophilic area than an end portion of the lyophilic area.

6. The substrate for forming a single crystal layer of claim 1, wherein one end portion of the crystal growth inducing rail part in a longitudinal direction is in a shape of an acute angle.

7. The substrate for forming a single crystal layer of claim 6, wherein an angle of the one end portion is in a range of about 30° to about 45°.

8. A method of preparing a single crystal layer, the method comprising:
providing a solution of a single crystal material on a substrate for forming a single crystal layer having a lyophilic area and a crystal growth inducing rail part; and
moving the solution of the single crystal material from one end portion of the crystal growth inducing rail part in a longitudinal direction toward another end portion of the crystal growth inducing rail part,
wherein the lyophilic area has a high affinity to the single crystal material to maintain the position of the solution of the single crystal material; and
wherein the crystal growth inducing rail part is formed in a shape of a line in the lyophilic area and has a higher affinity to the solution of the single crystal material than that of the lyophilic area.

9. The method of claim 8, wherein the crystal growth inducing rail part is formed across both ends of the lyophilic area in a crystal growth direction of the single crystal material.

10. The method of claim 9, wherein an end portion of the crystal growth inducing rail part in a width direction substantially perpendicular to the crystal growth direction is formed closer to a center of the lyophilic area than an end portion of the lyophilic area.

11. The method of claim 10, wherein one end portion of the crystal growth inducing rail part in a longitudinal direction is in a shape of an acute angle.

12. The method of claim 8, wherein an end portion of the crystal growth inducing rail part in a width direction substantially perpendicular to a longitudinal direction of the crystal growth inducing rail part is formed closer to a center of the lyophilic area than an end portion of the lyophilic area.

13. The method of claim 8, wherein one end portion of the crystal growth inducing rail part in a longitudinal direction is in a shape of an acute angle.

14. The method of claim 13, wherein an angle of the one end portion is in a range of about 30° to about 45°.
